(19) United States
(12) Patent Application Publication
(10) Pub. No.: US 2009/0145477 A1
(43) Pub. Date: Jun. 11, 2009

(54) SOLAR CELL

(75) Inventors: Won Ha Moon, Suwon (KR); Chang Hwan Choi, Sungnam (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/193,831

(22) Filed: Aug. 19, 2008

(30) Foreign Application Priority Data
Dec. 6, 2007 (KR) 10-2007-126118

(51) Int. Cl. H01L 31/00

(52) U.S. Cl. 136/256

(57) ABSTRACT

There is provided a solar cell including: a substrate; and an energy absorption structure formed on the substrate, the energy absorption structure including a metal layer, a semiconductor layer and an insulator formed therebetween, wherein at least one of the metal layer, the semiconductor layer and the insulator is formed of a plurality of nanowire structures. The solar cell has the energy absorption structure formed of a nanowire MIS junction structure to ensure high photoelectric conversion efficiency. Further, the solar cell does not require an epitaxial growth, thereby free from drawbacks of an epitaxial layer such as crystal defects.

### CROSS-REFERENCE TO RELATED APPLICATIONS

This application claims the priority of Korean Patent Application No. 2007-126118 filed on Dec. 6, 2007, in the Korean Intellectual Property Office, the disclosure of which is incorporated herein by reference.

### BACKGROUND OF THE INVENTION

1. Field of the Invention

The present invention relates to a solar cell, more particularly, having a nanowire metal insulator semiconductor (MIS) structure.

2. Description of the Related Art

Recently, with rising interests in environmental issues and energy depletion, a growing attention has been drawn on a solar cell as an alternative energy since the solar cell is free from environmental pollution and high in energy efficiency.

The solar cell is broken down into a solar thermal cell generating steam necessary for rotating a turbine using solar heat and a solar photon cell converting photons from the sun into electrical energy using semiconductor characteristics. Notably, studies have been vigorously conducted on the solar photon cell (hereinafter, referred to as “solar cell”) in which electrons of a p-type semiconductor and holes of an n-type semiconductor generated by absorption of light are converted into electrical energy.

FIG. 1 is a schematic conceptual view for explaining operation of a conventional solar cell. Referring to FIG. 1, the solar cell 10 includes a junction structure of n-type and p-type semiconductor layers 11 and 12 and electrode pads 13a and 13b formed on the n-type and p-type semiconductor layers 11 and 12 formed thereon, respectively.

A bulb 14 as a light emitting part is connected to the electrode pads 13a and 13b of the solar cell 10. Then, when the solar cell 10 is exposed to a light source such as a solar light L, current flows across the n-type semiconductor layer 11 and the p-type semiconductor layer 12 due to a photovoltaic effect, thereby generating electromotive force. This process is construed to be reverse to a process of a light emitting device such as a light emitting diode (LED) in which electrons and holes are re-combined to emit light.

As described above, the bulb 14 electrically connected to the solar cell 10 can be turned on by the electromotive force generated due to the photovoltaic effect.

In the conventional solar cell 10, for example, in a case where a pn junction is formed by a silicon semiconductor, the silicon has a bandgap energy of 1.1 eV, which corresponds to an infrared ray region. When the solar cell receives light having a bandgap energy of 2 eV, which corresponds to a visible light region, in principle, the energy efficiency is about 50%.

Based on this photon energy efficiency, the single crystal solar cell made of silicon has a theoretical efficiency of maximum 45%, but a practical efficiency of 28% considering other losses.

Besides, a solar cell made of a single semiconductor material absorbs light of the partial wavelength, out of a wavelength ranging from 300 to 1800 nm, thereby not absorbing the solar light with efficiency.

This accordingly has led to a need in the art for manufacturing a solar cell with higher efficiency.

### SUMMARY OF THE INVENTION

An aspect of the present invention provides a solar cell having an energy absorption structure formed of a nanowire metal insulator semiconductor (MIS) structure to ensure high photoelectric conversion efficiency.

According to an aspect of the present invention, there is provided a solar cell including: a substrate; and an energy absorption structure formed on the substrate, the energy absorption structure including a metal layer, a semiconductor layer and an insulator formed therebetween, wherein at least one of the metal layer, the semiconductor layer and the insulator is formed of a plurality of nanowire structures.

The metal layer, the semiconductor layer and the insulator may integrally form a nanowire structure.

The insulator may be formed of one of an oxide and a nitride. The insulator may be formed of one of the oxide and the nitride including at least one element selected from a group consisting of Si, Al, Zr and Hf.

The insulator may have a thickness of 0.1 to 5 nm.

The nanowire structures each may have a diameter of 5 to 500 nm.

The solar cell may further include a transparent electrode layer formed on the energy absorption structure.

According to another aspect of the present invention, there is provided a solar cell including: a substrate; and an energy absorption structure formed on the substrate, the energy absorption structure including a transparent conductive oxide layer, a semiconductor layer and an insulator formed therebetween, wherein at least one of the transparent oxide layer, the semiconductor layer and the insulator is formed of a plurality of nanowire structures.

The transparent conductive oxide layer may include at least one material selected from a group consisting of ITO, ZnO, AlZnO and InZnO.

The energy absorption structure may be formed of a multilayer structure having a plurality of layers connected to one another by a tunneling layer.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic conceptual view for explaining a conventional solar cell;

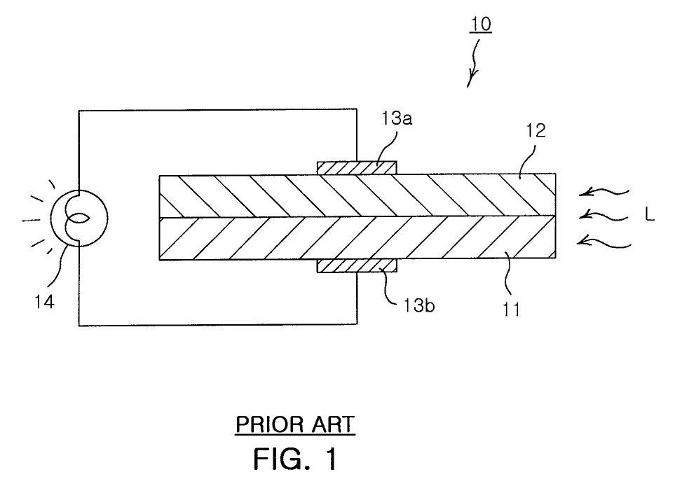

FIG. 2 is a cross-sectional view illustrating a solar cell according to an exemplary embodiment of the invention;

FIG. 3 is a detailed perspective view illustrating a nanowire structure of FIG. 2;

FIG. 4A is a cross-sectional view illustrating a device using a metal insulator semiconductor (MIS) structure;

FIG. 4B is an energy diagram for explaining a light emission mechanism of an MIS structure;

FIG. 5 is a cross-sectional view illustrating a modified example of a solar cell shown in FIG. 2 according to an exemplary embodiment of the invention;

FIG. 6 is across-sectional view illustrating a modified example of a solar cell shown in FIG. 2 according to an exemplary embodiment of the invention; and

FIG. 7 is a cross-sectional view illustrating a solar cell according to another exemplary embodiment of the invention.

### DETAILED DESCRIPTION OF THE PREFERRED EMBODIMENT

Exemplary embodiments of the present invention will now be described in detail with reference to the accompanying drawings. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity, and the same reference signs are used to designate the same or similar components throughout.

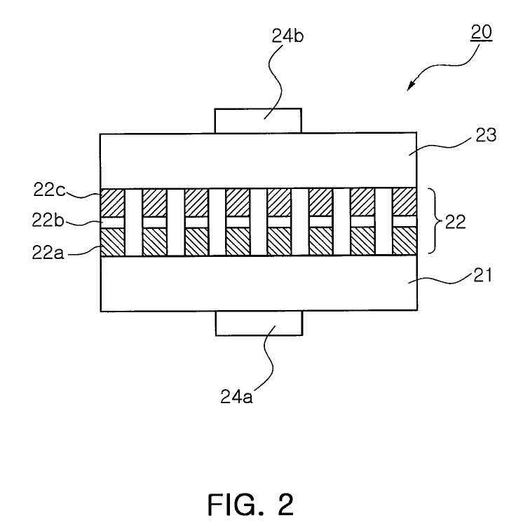

FIG. 2 is a cross-sectional view illustrating a solar cell according to an exemplary embodiment of the invention.

Referring to FIG. 2, the solar cell 20 of the present embodiment includes a substrate 21, an energy absorption structure 22, a transparent electrode layer 23, and first and second electrodes 24a and 24b.

The energy absorption structure 22 receives solar light to generate an electromotive force, and is formed of a plurality of nanowire structures. Each of the nanowires structures includes a semiconductor layer 22a, an insulator 22b and a metal layer 22c.

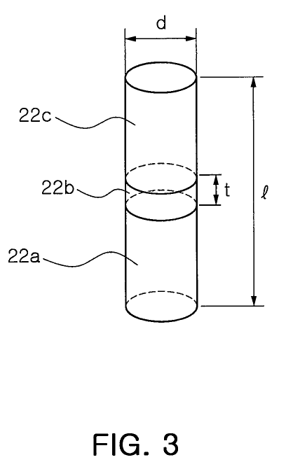

FIG. 3 is a detailed perspective view illustrating a nanowire structure of FIG. 2. Referring to FIG. 3, in the present embodiment, the nanowire structure 22a, 22b and 22c features a metal insulator semiconductor (MIS) structure formed of metal-insulator-semiconductor.

A device with this MIS structure requires a fewer number of layers than a device obtained by single crystal thin film growth to ensure a simple solar cell structure. This accordingly simplifies a manufacturing process. Also, the device with the MIS structure does not require epitaxial growth, thus not entailing drawbacks of an epitaxial layer such as crystal defects.

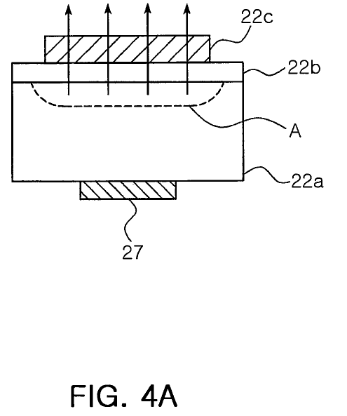

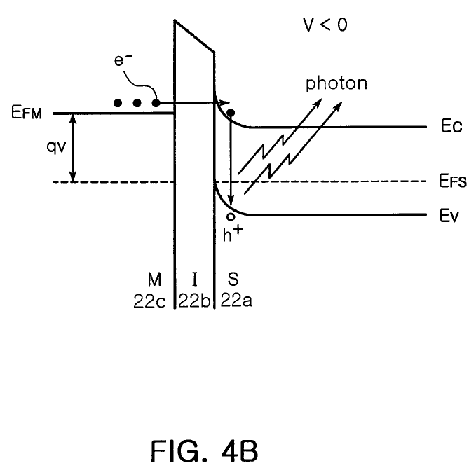

The MIS structure will be described with reference to FIGS. 4A and 4B.

First, FIG. 4A is a cross-sectional view illustrating a device with the MIS structure.

Hereinafter, for convenience's sake, unlike the present embodiment, an explanation will be given based on a light emitting device capable of emitting light when power is applied. However, a reversal in the operational principle of the light emitting device will lead to understanding of the operational principle of a solar cell.

The MIS structure includes a semiconductor layer 22a, an insulator 22b, and a metal layer 22c. Here, as shown in FIG. 4A, an electrode 27 is additionally formed on a bottom of the semiconductor layer 22a.

Light emission occurs in an A area of the semiconductor layer 22a. Light is emitted from the A area due to recombination caused by tunneling of electrons from metal.

FIG. 4B is an energy diagram illustrating such light emission mechanism. FIG. 4B shows energy levels when a negative (−) voltage is applied to the metal layer 22c and a positive (+) voltage is applied to the semiconductor layer 22a, respectively.

Upon application of the positive (−) voltage to the metal layer 22c, electrons e⁻ migrate through the insulator 22b by tunneling effects. Such electrons e⁻ reach the semiconductor layer 22a and then the electrons e⁻ are combined with holes h⁺ in a valence band to thereby generate photons.

When the operational principle of the MIS light emitting device described above is reversely applied to the solar cell, the A area of the solar cell mainly receives solar light and has current flowing therein by tunneling of electrons e⁻.

Electrical energy generated in this fashion may be collected by a capacitor (not shown) connected to the first and second electrodes 24a and 24b shown in FIG. 2.

Referring back to FIG. 3, the MIS structure employed in the energy absorption structure features a nanowire structure 22a, 22b and 22c to increase photoelectric conversion efficiency.

Meanwhile, when it comes to a ‘nanowire’ used in the specification, first, a ‘nanorod’ denotes a material shaped as a rod having a diameter ranging from several nm to tens of nm. Here, the nanorod, when elongated into a wire shape, is considered a ‘nanowire’.

As in the present embodiment, the energy absorption structure serving as an area for receiving light is formed of a plurality of nanowire structures to enhance quantum effect and overall light receiving area. This accordingly brings about considerable increase in light receiving efficiency. In the present embodiment, the light receiving area adopts a nanowire structure but may employ a nanorod with a smaller length than the nanowire.

Further, as described above, the energy absorption structure is not a semiconductor crystal formed on the substrate by thin film growth, thus undergoing very few crystal defects, and accordingly leading to higher photoelectric conversion efficiency.

Here, the insulator 22b may have a thickness t of 0.1 to 5 nm considering tunneling of electrons.

Meanwhile, referring to FIG. 2, the nano wire structures 22a, 22b and 22c of the energy absorption structure 22 have voids therebetween filled with air or transparent material to prevent decline in light absorption.

The substrate 21 may reflect solar light to be directed to the energy absorption structure 22. However, the substrate 21 may be formed of a transparent material.

In the same manner, in the present embodiment, a transparent electrode layer 23 is formed on the energy absorption structure 22, but the transparent electrode layer may be substituted by a solar light reflective layer. In this case, the substrate 21 may be formed of a transparent electrode layer. That is, in the present embodiment, the substrate 21 and the transparent electrode layer 23 enclosing the energy absorption structure 22 of nanowire structures may be changed in position from each other considering an incident direction of the solar light. Also, both the substrate 21 and the transparent electrode layer 23 may be formed of a transparent electrode layer or a reflective layer.

However, the transparent electrode layer 23 is not an essential element and may not be formed.

Meanwhile, the semiconductor layer 22a may be formed of a silicon semiconductor, a GaN-based semiconductor, a ZnO-based semiconductor, a GaAs-based semiconductor, a GaP-based semiconductor, or a GaAsP-based semiconductor.

Here, the semiconductor layer 22a may be formed of a suitable material in view of wavelength band of the absorbable solar light. Specifically, the material for the semiconductor layer 22a may utilize AlGaInP (2.1 eV), InGaP (1.9 eV), AlGaInAs (1.6 eV), InGaAs (1 eV), and Ge (0.7 eV). Parentheses denote an approximate energy value of the absorbable solar light.

Also, the metal layer 22c of the MIS structure is not necessarily formed of a metal but may employ other conductive material. The metal layer may be formed of a transparent conductive oxide (TCO).

A material as the transparent conductive oxide includes Indium Tin oxide (ITO), ZnO, AlZnO, and InZnO.

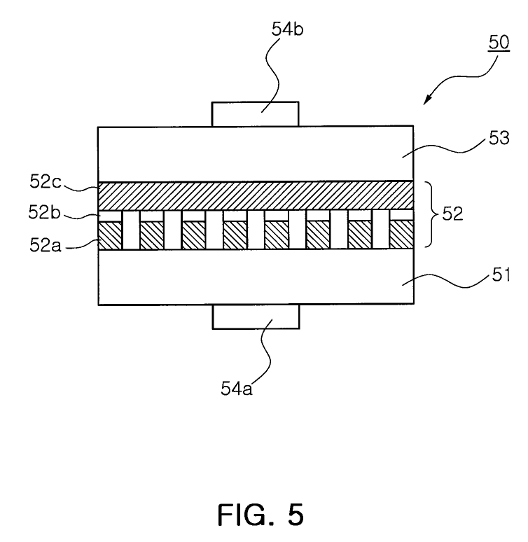

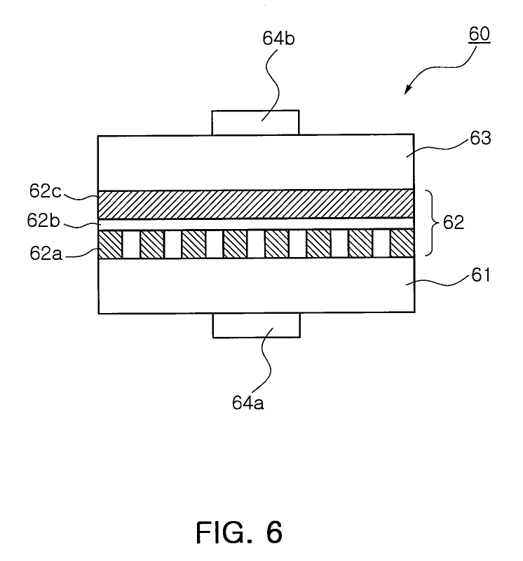

FIGS. 5 and 6 are cross-sectional views illustrating modified examples of a solar cell shown in FIG. 2, respectively according to other embodiments of the invention.

First, in the same manner as FIG. 2, the solar cell 50 of the present embodiment shown in FIG. 5 includes a substrate 51, an energy absorption structure 52, a transparent electrode layer 53, and first and second electrodes 54a and 54b.

In the present embodiment, the nanowire structure of the energy absorption structure shown in FIG. 2 is formed to include a semiconductor layer 52a and an insulator 52b. Also, a metal layer 52c is formed of a thin film. In the solar cell 50 of FIG. 5, other constituents are identical to those of FIG. 2, and thus will not be described in further detail.

In the same manner as FIG. 2, the solar cell of FIG. 6 includes a substrate 61, an energy absorption structure 62, a transparent electrode layer 63, and first and second electrodes 64a and 64b.

In the present embodiment, the nanowire structure of the energy absorption structure shown in FIG. 2 is formed to include only a semiconductor layer 62a, and an insulator 62b and a metal layer 62c are formed of only a thin film. In the solar cell 60 of FIG. 6, other constituents are identical to those of FIG. 2, and thus will not be described in further detail.

FIGS. 5 and 6 show examples applicable to the present invention, and the nanowire structure may include at least one of a semiconductor layer, an insulator and a metal layer.

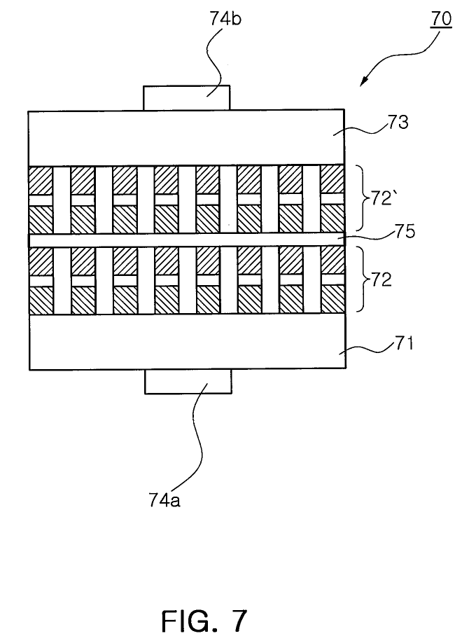

FIG. 7 is a cross-sectional view illustrating a solar cell according to another exemplary embodiment of the invention.

In the same manner as the solar cells described above, the solar cell 70 of the present embodiment includes a substrate 71, energy absorption structures 72 and 72′, a transparent electrode layer 73, and first and second electrodes 74a, and 74b.

In the present embodiment, the energy absorption structure of FIG. 2 is expanded into two layers of energy absorption structures, and will not be described in further detail.

As shown in FIG. 7, unlike the solar cells described above, the solar cell 70 includes first and second energy absorption structures 72a and 72b and a tunneling layer 75 interposed therebetween to enable tunneling of carriers. The energy absorption structures 72a and 72b of a multi-layer structure increase light abortion and wavelength band of absorbable light.

Of course, in this case, a material for the energy absorption structures and tunneling layer and the number of layers may be varied adequately.

As set forth above, in a solar cell according to exemplary embodiments of the invention, an energy absorption structure is formed of a nanowire MIS junction structure to ensure high photoelectric conversion efficiency.

In addition, the solar cell does not require an epitaxial growth, thus free from drawbacks of an epitaxial layer such as crystal defects.

While the present invention has been shown and described in connection with the exemplary embodiments, it will be apparent to those skilled in the art that modifications and variations can be made without departing from the spirit and scope of the invention as defined by the appended claims.

What is claimed is:

1. A solar cell comprising:
a substrate; and
an energy absorption structure formed on the substrate, the energy absorption structure comprising a metal layer, a semiconductor layer and an insulator formed therebetween,
wherein at least one of the metal layer, the semiconductor layer and the insulator is formed of a plurality of nanowire structures.

2. The solar cell of claim 1, wherein the metal layer, the semiconductor layer and the insulator integrally form a nanowire structure.

3. The solar cell of claim 1, wherein the insulator is formed of one of an oxide and a nitride.

4. The solar cell of claim 3, wherein the insulator is formed of one of the oxide and the nitride comprising at least one element selected from a group consisting of Si, Al, Zr and Hf.

5. The solar cell of claim 1, wherein the insulator has a thickness of 0.1 to 5 nm.

6. The solar cell of claim 1, wherein the nanowire structures each have a diameter of 5 to 500 nm.

7. The solar cell of claim 1, further comprising a transparent electrode layer formed on the energy absorption structure.

8. A solar cell comprising:
a substrate; and
an energy absorption structure formed on the substrate, the energy absorption structure comprising a transparent conductive oxide layer, a semiconductor layer and an insulator formed therebetween,
wherein at least one of the transparent oxide layer, the semiconductor layer and the insulator is formed of a plurality of nanowire structures.

9. The solar cell of claim 8, wherein the transparent conductive oxide layer comprises at least one material selected from a group consisting of ITO, ZnO, AlZnO and InZnO.

10. The solar cell of claim 1, wherein the energy absorption structure is formed of a multilayer structure having a plurality of layers connected to one another by a tunneling layer.
